(19) United States
(12) Patent Application Publication
(10) Pub. No.: US 2026/0196267 A1
(43) Pub. Date: Jul. 9, 2026

(54) MEMORY DEVICE AND MEMORY SYSTEM

(71) Applicant: MACRONIX INTERNATIONAL CO., LTD., HSINCHU (TW)

(72) Inventor: Po-Hao TSENG, Taichung City (TW)

(21) Appl. No.: 19/289,226

(22) Filed: Aug. 4, 2025

Related U.S. Application Data
(60) Provisional application No. 63/742,434, filed on Jan. 7, 2025.

(51) Int. Cl. G11C 15/04; G11C 16/04

(52) U.S. Cl. CPC G11C 15/046; G11C 16/0483

(57) ABSTRACT

A memory device includes a memory string configured to store first stored data, and configured to compare the first stored data and first input data to generate a first current signal. The memory string includes a plurality of switch elements coupled in series with each other, the plurality of switch elements including: a first switch element configured to have a first threshold voltage when the first stored data has a first value, and have a second threshold voltage when the first stored data has a first encoding range; and a second switch element configured to have the second threshold voltage when the first stored data has the first value, and have the second threshold voltage when the first stored data has the first encoding range, wherein the first encoding range at least comprises the first value and a second value different from the first value.

### CROSS - REFERENCE TO RELATED APPLICATION

This application claims priority to U.S. Provisional Application No. 63/742,434, filed January 07, 2025, which is herein incorporated by reference in its entirety.

### BACKGROUND

### Technical Field

The present disclosure relates to a memory technique. More particularly, the present disclosure relates to a memory device and a memory system.

### Description of Related Art

As the raising of big data and AI hardware accelerator, the data comparing/searching is essential functions for these two directions. Highly parallel searching can be implemented by the existing ternary content addressable memory (TCAM). Conventional TCAM is typically composed of SRAM thus suffer low memory density (16T as one TCAM cell) and high access power. To save power consumption with dense memory density, the nonvolatile based TCAM arrays were proposed recently (2T2R, 2FeFET, and so on). In-3D-NAND flash searching architecture is proposed for high performance searching capability. This architecture can be used in various fields, such as Big-data searching, AI hardware accelerator/classifier, Approximate Computing, Analog Computing, Associative memory, few-shot learning, SSD data managements, DNA matching, Data filter, Hyper-dimensional computing and so on.

### SUMMARY

The present disclosure provides a memory device. The memory device comprises a memory string configured to store first stored data, and configured to compare the first stored data and first input data to generate a first current signal. The memory string comprises a plurality of switch elements coupled in series with each other, the plurality of switch elements comprising: a first switch element configured to have a first threshold voltage when the first stored data has a first value, and have a second threshold voltage when the first stored data has a first encoding range; and a second switch element configured to have the second threshold voltage when the first stored data has the first value, and have the second threshold voltage when the first stored data has the first encoding range, wherein the first encoding range at least comprises the first value and a second value different from the first value.

In some embodiments, the memory string is further configured to receive a plurality of word line signals, the plurality of word line signals are configured to carry the first input data, when the first input data has the first value and the first stored data have the first encoding range, the first current signal has a first current level.

In some embodiments, when the first input data has a third value and the first stored data have the first encoding range, the first current signal has a second current level.

In some embodiments, the third value is out of the first encoding range , and the second current level is smaller than the first current level.

In some embodiments, a control terminal of the first switch element is configured to receive a first word line signal in the plurality of word line signals, a control terminal of the second switch element is configured to receive a second word line signal in the plurality of word line signals, when the first stored data has the first value, the first word line signal and the second word line signal have a first voltage level and a second voltage level, respectively, and when the first stored data has the first encoding range, each of the first word line signal and the second word line signal has the first voltage level.

In some embodiments, when the first stored data has the first encoding range, a third word line signal in the plurality of word line signals has the second voltage level, when the first stored data has a second encoding range, the third word line signal has the first voltage level, and the second encoding range is larger than the first encoding range.

In some embodiments, the first voltage level is larger than the second voltage level.

In some embodiments, when the first stored data has a third encoding range, the first word line signal and the second word line signal have a third voltage level and a fourth voltage level, respectively, and the first voltage level, the second voltage level, the third voltage level and the fourth voltage level are different from each other.

In some embodiments, each of the third voltage level and the fourth voltage level is between the first voltage level and the second voltage level.

In some embodiments, when the first stored data has the third encoding range and the first stored data has the first value, the first current signal has a second current level.

In some embodiments, the first value is out of the third encoding range, and the second current level is smaller than the first current level.

In some embodiments, when the first stored data has the third encoding range and the first stored data has the first value, the first switch element is turned off.

The present disclosure provides a memory device. The memory device comprises a memory string configured to store first stored data, and configured to compare the first stored data and first input data to generate a first current signal. The memory string comprises a plurality of switch elements coupled in series with each other, the plurality of switch elements comprising: a first switch element configured to receive a first word line signal, have a first threshold voltage when the first stored data has a first value, and have a second threshold voltage when the first stored data has a first encoding range; and a second switch element configured to receive a second word line signal, have the second threshold voltage when the first stored data has the first value, and have the second threshold voltage when the first stored data has the first encoding range, wherein the first encoding range at least comprises the first value and a second value different from the first value.

In some embodiments, when the first input data has the first value, the first word line signal and the second word line signal have a first voltage level and a second voltage level, respectively, and when the first stored data has the first encoding range, each of the first word line signal and the second word line signal has the first voltage level.

In some embodiments, when the first input data has a third value, the first word line signal and the second word line signal have a third voltage level and a fourth voltage level, respectively, and the first voltage level, the second voltage level, the third voltage level and the fourth voltage level are different from each other.

In some embodiments, when the first input data has the third value and the first stored data has the first encoding range, a third switch element in the plurality of switch element is turned off, and the third value is out of the first encoding range.

In some embodiments, when the first stored data has the first encoding range, each of the first word line signal and the second word line signal has the first voltage level.

The present disclosure provides a memory system. The memory system comprises a plurality of text chunk configured to generate a plurality of bit line signals, respectively, and comprising a plurality of memory strings, the plurality of memory strings comprising: a first memory string configured to store first stored data, configured to receive a plurality of word line signals carrying first input data, and configured to compare the first stored data and the first input data to generate a first current signal, wherein in response to the first input data has a first encoding range and the first stored data has a first value, the first current signal has a first current level, and the first encoding range includes the first value.

In some embodiments, the first encoding range further includes a second value different from the first value.

In some embodiments, in response to the first input data has the first encoding range, each of at least two switch elements in the first memory string has a first threshold voltage level, and the at least two switch elements are arranged in order.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a part of a memory device illustrated according to some embodiments of present disclosure.

FIG. 2 is a table of a part of the thermometer encoding with range of the stored data, illustrated according to some embodiments of present disclosure.

FIG. 3A to FIG. 3E are schematic diagrams of the memory device performing the search operation, illustrated according to some embodiments of present disclosure.

FIG. 4 is a schematic diagram of various values and encoding ranges of the stored data, illustrated according to some embodiments of present disclosure.

FIG. 5A is a schematic diagram of a memory system illustrated according to some embodiments of present disclosure.

FIG. 5B is schematic diagram of further details of the memory system shown in FIG. 5A, illustrated according to some embodiments of present disclosure.

FIG. 5C is schematic diagram of further details of the query data, illustrated according to some embodiments of present disclosure.

FIG. 5D is schematic diagram of further details of the memory strings, illustrated according to some embodiments of present disclosure.

### DETAILED DESCRIPTION

In the present disclosure, when an element is referred to as "connected" or "coupled", it may mean "electrically connected" or "electrically coupled". "Connected" or "coupled" can also be used to indicate that two or more components operate or interact with each other. In addition, although the terms "first", "second", and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms "a", "one" and "the" are also intended to include plural forms, unless the context clearly indicates otherwise. It will be further understood that when used in this specification, the terms "comprises (comprising)" and/or "includes (including)" designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

The present disclosure provides a three-dimensional NAND (3D-NAND) artificial intelligence (AI) engine with thermometer range encoding in single layer cell (SLC) and multi-level cell (MLC). The multi-level thermometer range encoding can reduce the number of NAND units for designed quantized levels in the memory string and also extend the quantized level of a feature value to boost matching capability for high performance AI accelerator. Moreover, the multi-level thermometer range encoding can also enhance the NAND array efficiency for large database storage.

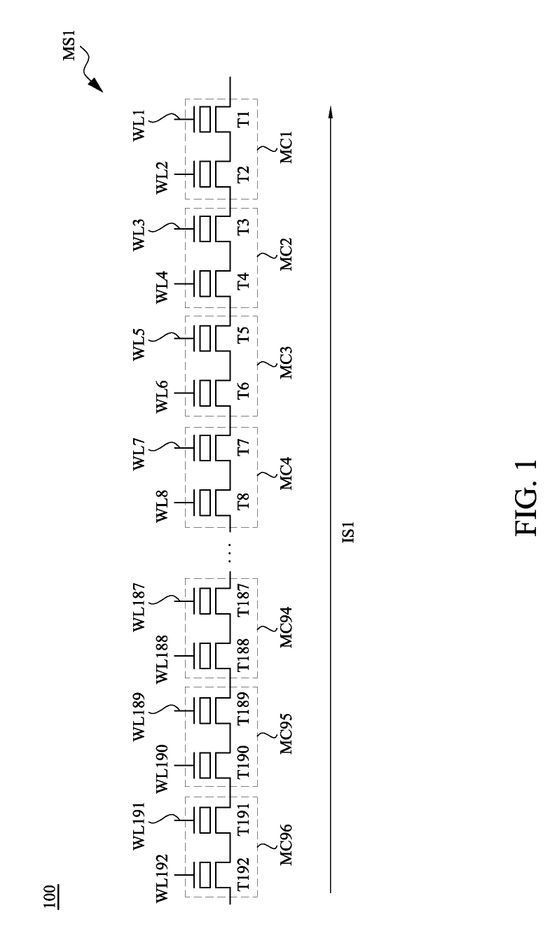

FIG. 1 is a schematic diagram of a part of a memory device 100, illustrated according to some embodiments of present disclosure. In some embodiments, the memory device 100 can include and multiple memory stings, such as the memory string MS1. The memory string MS1 is configured to store the stored data SDT1, and is configured to compare the input data IDT1 and the stored data SDT1 to generate a string current signal IS1. In some embodiments, the stored data SDT1 can be implemented by stored feature data, and the input data IDT1 can be implemented by input feature data.

As shown in FIG. 1, the memory string MS1 includes multiple switch elements, such as the switch elements T1~T192. In some embodiments, the switch elements T1~T192 are coupled in series with each other and arranged in order. In some embodiments, the switch elements T1~T192 are located in 192 memory layers, respectively, and can be implemented by MLC. Alternatively stated, the memory string MS1 can be implemented by 192 layers of MLC. Control terminals of the switch elements T1~T192 are configured to receive word line signals WL1~WL192, respectively. However, the present disclosure is not limited to this. In various embodiments, the memory device 100 can include various quantities of memory strings. Alternatively stated, 32 can be substituted by other positive integers.

In some embodiments, adjacent two switch elements can operate as one memory cell. Specifically, the switch elements T1 and T2 can operate as a memory cell MC1. The switch elements T3 and T4 can operate as a memory cell MC2. The switch elements T5 and T6 can operate as a memory cell MC3. The switch elements T7 and T8 can operate as a memory cell MC4, and so on. The switch elements T187 and T188 can operate as a memory cell MC94. The switch elements T189 and T190 can operate as a memory cell MC95. The switch elements T191 and T192 can operate as a memory cell MC96.

In summary, the memory string MS1 includes 96 memory cells MC1~MC96 coupled in series with each other and arranged in order. In some embodiments, the stored data SDT1 includes 96 stored data bits SDB1~SDB96. The memory cells MC1~MC96 are configured to store the stored data bits SDB1~SDB96, respectively.

In the embodiments that the memory string MS1 is implemented by MLC, each of the stored data bits SDB1~SDB96 can have logic values 0, 1, 2 or 3. When a stored data bit has the logic value 0, corresponding two switch elements have threshold voltage levels VT4 and VT1, respectively. When a stored data bit has the logic value 1, corresponding two switch elements have threshold voltage levels VT3 and VT2, respectively. When a stored data bit has the logic value 2, corresponding two switch elements have the threshold voltage levels VT2 and VT3, respectively. When a stored data bit has the logic value 3, corresponding two switch elements have the threshold voltage levels VT1 and VT4, respectively. When a stored data bit has a don’t care logic value X, each of corresponding two switch elements has threshold voltage level VT1.

For example, for the memory cell MC1, when the stored data bit SDB1 has the logic value 0, the switch elements T1 and T2 have the threshold voltage levels VT4 and VT1, respectively. When the stored data bit SDB1 has the logic value 1, the switch elements T1 and T2 have the threshold voltage levels VT3 and VT2, respectively. When the stored data bit SDB1 has the logic value 2, the switch elements T1 and T2 have the threshold voltage levels VT2 and VT3, respectively. When the stored data bit SDB1 has the logic value 3, the switch elements T1 and T2 have the threshold voltage levels VT1 and VT4, respectively. When the stored data bit SDB1 has the don’t care logic value X, each of the switch elements T1 and T2 has the threshold voltage level VT1. Each of configurations of the memory cells MC2-MC96 can be similar to the configuration of the memory cell MC1 described above.

In some embodiments, the don’t care logic value X is referred to as an arbitrary logic value during storage. The don’t care logic value X can represent different logic values. In the embodiment shown in FIG. 1, the don’t care logic value X can represent anyone of the logic values 0~3. In some embodiments, the threshold voltage level VT1 is smaller than the threshold voltage level VT2. The threshold voltage level VT2 is smaller than the threshold voltage level VT3. The threshold voltage level VT3 is smaller than the threshold voltage level VT4.

On the other hand, the input data IDT1 includes 96 input data bits IDB1~IDB96. Two word line signals in the word lines WL1~WL192 are configured to carry a corresponding one of the input data bits IDB1~IDB96. Specifically, the word line signals WL1 and WL2 are configured to carry the input data bit IDB1. The word line signals WL3 and WL4 are configured to carry the input data bit IDB2, and so on. The word line signals WL191 and WL192 are configured to carry the input data bit IDB96.

In some embodiments, each of the input data bits IDB1~IDB96 can have the logic values 0, 1, 2 or 3. When an input data bit has the logic value 0, corresponding two word line signals have voltage levels VS1 and VS4, respectively. When an input data bit has the logic value 1, corresponding two word line signals have voltage levels VS2 and VS3, respectively. When an input data bit has the logic value 2, corresponding two word line signals have voltage levels VS3 and VS2, respectively. When an input data bit has the logic value 3, corresponding two word line signals have voltage levels VS4 and VS1, respectively. When an input data bit has the wildcard logic value W, each of corresponding two word line signals has voltage level VS4.

For example, when the input data bit IDB1 the logic value 0, the word line signals WL1 and WL2 have voltage levels VS1 and VS4, respectively. When the input data bit IDB1 the logic value 1, the word line signals WL1 and WL2 have voltage levels VS2 and VS3, respectively. When the input data bit IDB1 the logic value 2, the word line signals WL1 and WL2 have voltage levels VS3 and VS2, respectively. When the input data bit IDB1 the logic value 3, the word line signals WL1 and WL2 have voltage levels VS4 and VS1, respectively. When the input data bit IDB1 the wildcard logic value W, each of the word line signals WL1 and WL2 have voltage level VS4, respectively. Each of configurations of the word line signals WL3~WL192 can be similar to the configuration of the word line signals WL1 and WL2 described above.

In some embodiments, the wildcard logic value W is referred to as an arbitrary logic value during input. The wildcard logic value W can represent different logic values. In the embodiment shown in FIG. 1, the wildcard logic value W can represent anyone of the logic values 0~3.

In some embodiments, the voltage level VS1 is between the threshold voltage levels VT1 and VT2. The voltage level VS2 is between the threshold voltage levels VT2 and VT3. The voltage level VS3 is between the threshold voltage levels VT3 and VT4. The voltage level VS4 is larger than the threshold voltage level VT4.

Alternatively stated, when a switch element has the threshold voltage level VT1, in response to the control terminal of the switch element having anyone of the voltage levels VS1~VS4, the switch element is turned on. When a switch element has the threshold voltage level VT2, in response to the control terminal of the switch element having anyone of the voltage levels VS2~VS4, the switch element is turned on, and in response to the control terminal of the switch element having the voltage level VS1, the switch element is turned off. When a switch element has the threshold voltage level VT3, in response to the control terminal of the switch element having anyone of the voltage levels VS3~VS4, the switch element is turned on, and in response to the control terminal of the switch element having anyone of the voltage levels VS1~VS2, the switch element is turned off. When a switch element has the threshold voltage level VT4, in response to the control terminal of the switch element having the voltage level VS4, the switch element is turned on, and in response to the control terminal of the switch element having anyone of the voltage levels VS1~VS3, the switch element is turned off.

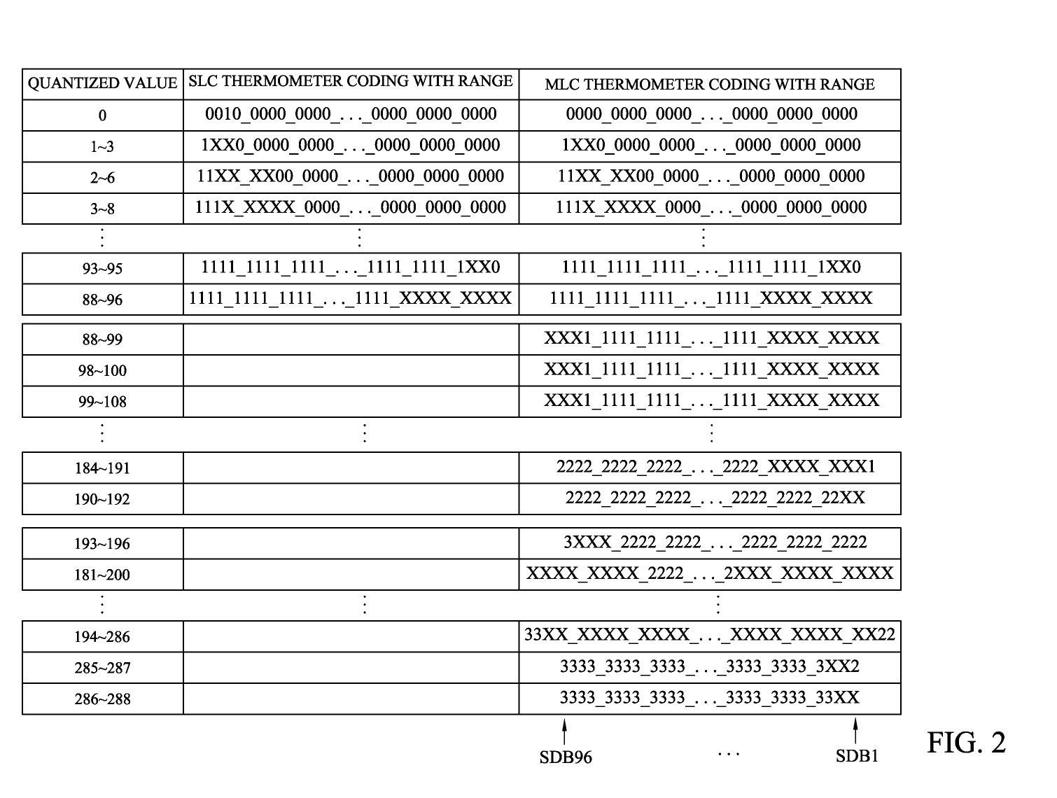

FIG. 2 is a table 200 of a part of the thermometer encoding with range of the stored data, illustrated according to some embodiments of present disclosure. The thermometer encoding shown in the table 200 can be used for SLC and MLC. In various embodiments, the stored data described in the present disclosure can be implemented by various types of stored data, such as stored data of image type of audio type.

Referring to FIG. 1 and FIG. 2, the table 200 represent a relationship between various encoding ranges of the stored data SDT1 and corresponding logic values of the stored data bits SDB1~SDB96. For various encoding ranges, the stored data SDT1 can have various values. In some embodiments, the value of the stored data SDT1 described above can be referred to as a quantized value of the stored data SDT1.

As shown in the table 200, when the value of the stored data SDT1is equal to 0, each of the stored data bits SDB1~SDB96 has the logic value 0. When the stored data SDT1has an encoding range 1~3, the value of the stored data SDT1 can be equal to any value in the encoding range 1~3. Correspondingly, the stored data bit SDB96 has the logic value 1, each of the stored data bits SDB95 and SDB94 has the don’t care logic value X, and each of the stored data bits SDB1~SDB93 has the logic value 0.

When the stored data SDT1 has an encoding range 2~6, the value of the stored data SDT1 can be equal to any value in the encoding range 2~6. Correspondingly, each of the stored data bits SDB95 and SDB96 has the logic value 1, each of the stored data bits SDB91~SDB94 has the don’t care logic value X, and each of the stored data bits SDB1~SDB90 has the logic value 0.

When the stored data SDT1 has an encoding range 3~8, the value of the stored data SDT1 can be equal to any value in the encoding range 3~8. Correspondingly, each of the stored data bits SDB94~SDB96 has the logic value 1, each of the stored data bits SDB89~SDB93 has the don’t care logic value X, and each of the stored data bits SDB1~SDB88 has the logic value 0.

When the stored data SDT1 has an encoding range 93~95, the value of the stored data SDT1 can be equal to any value in the encoding range 93~95. Correspondingly, each of the stored data bits SDB4~SDB96 has the logic value 1, each of the stored data bits SDB2~SDB3 has the don’t care logic value X, and the stored data bit SDB1 has the logic value 0.

When value of the stored data SDT1 has an encoding range 88~96, the value of the stored data SDT1 can be equal to any value in the encoding range 88~96. Correspondingly, each of the stored data bits SDB9~SDB96 has the logic value 1, and each of the stored data bits SDB1~SDB8 has the don’t care logic value X.

In summary, for conditions of the values of the stored data SDT1 smaller than 96, the minimum value in the encoding range is equal to a quantity of stored data bits having the logic value 1. For example, when the stored data SDT1 has the encoding range 3~8, the minimum value in the encoding range 3~8 is equal to 3, in which 3 is equal to the quantity of the stored data bits SDB94~SDB96 having the logic value 1. For another example, when the stored data SDT1 has the encoding range 88~96, the minimum value in the encoding range 88~96 is equal to 88, in which 88 is equal to the quantity of the stored data bits SDB9~SDB96 having the logic value 1.

Furthermore, a size of the encoding range is equal to a quantity of stored data bits having the don’t care logic value X. In some embodiments, the size of the encoding range is referred to as a difference between a maximum value and a minimum value in the encoding range. For example, when the stored data SDT1 has the encoding range 3~8, the difference between the maximum value 8 and the minimum value 3 in the encoding range 3~8 is equal to 5, in which 5 is equal to the quantity of the stored data bits SDB89~SDB93 having the don’t care logic value X. For another example, when the stored data SDT1 has the encoding range 88~96, the difference between the maximum value 96 and the minimum value 88 in the encoding range 88~96 is equal to 8, in which 8 is equal to the quantity of the stored data bits SDB1~SDB8 having the don’t care logic value X.

Then, referring to the table 200 again, when the value of the stored data SDT1 has an encoding range 88~99, the value of the stored data SDT1 can be equal to any value in the encoding range 88~99. Correspondingly, each of the stored data bits SDB9~SDB93 has the logic value 1, and each of the stored data bits SDB94~SDB96 and SDB1~SDB8 has the don’t care logic value X.

When the value of the stored data SDT1 has an encoding range 98~100, the value of the stored data SDT1 can be equal to any value in the encoding range 98~100. Correspondingly, each of the stored data bits SDB95~SDB96 has the logic value 2, each of the stored data bits SDB93~SDB94 has the don’t care logic value X, and each of the stored data bits SDB1~SDB92 has the logic value 1.

When the value of the stored data SDT1 has an encoding range 99~108, the value of the stored data SDT1 can be equal to any value in the encoding range 99~108. Correspondingly, each of the stored data bits SDB94~SDB96 has the logic value 2, each of the stored data bits SDB85~SDB93 has the don’t care logic value X, and each of the stored data bits SDB1~SDB84 has the logic value 1.

When the value of the stored data SDT1 has an encoding range 184~191, the value of the stored data SDT1 can be equal to any value in the encoding range 184~191. Correspondingly, each of the stored data bits SDB9~SDB96 has the logic value 2, each of the stored data bits SDB2~SDB8 has the don’t care logic value X, and the stored data bit SDB1 has the logic value 1.

When the value of the stored data SDT1 has an encoding range 190~192, the value of the stored data SDT1 can be equal to any value in the encoding range 190~192. Correspondingly, each of the stored data bits SDB3~SDB96 has the logic value 2, and each of the stored data bits SDB1~SDB2 has the don’t care logic value X.

In summary, for conditions of the values of the stored data SDT1 smaller than 192, when a quantity of stored data bits having the logic value 2 is more, the minimum value in the encoding range is larger. For example, when the stored data SDT1 has the encoding range 99~108, the minimum value in the encoding range 99~108 is equal to 99, and the quantity of the stored data bits SDB94~SDB96 having the logic value 2 is equal to 3. When the stored data SDT1 has the encoding range 184~191, the minimum value in the encoding range 184~191 is equal to 184, and the quantity of the stored data bits SDB94~SDB96 having the logic value 2 is equal to 88.

When the value of the stored data SDT1 has an encoding range 193~196, the value of the stored data SDT1 can be equal to any value in the encoding range 193~196. Correspondingly, the stored data bit SDB96 has the logic value 3, each of the stored data bits SDB93~SDB95 has the don’t care logic value X, and each of the stored data bits SDB1~SDB92 has the logic value 2.

When the value of the stored data SDT1 has an encoding range 181~200, the value of the stored data SDT1 can be equal to any value in the encoding range 181~200. Correspondingly, each of the stored data bits SDB89~SDB96 and SDB1~SDB11 has the don’t care logic value X, and each of the stored data bits SDB12~SDB88 has the logic value 2.

When the value of the stored data SDT1 has an encoding range 194~286, the value of the stored data SDT1 can be equal to any value in the encoding range 194~286. Correspondingly, each of the stored data bits SDB95~SDB96 has the logic value 3, each of the stored data bits SDB3~SDB94 has the don’t care logic value X, and each of the stored data bits SDB1~SDB2 has the logic value 2.

When the value of the stored data SDT1 has an encoding range 285~287, the value of the stored data SDT1 can be equal to any value in the encoding range 285~287. Correspondingly, each of the stored data bit SDB95~SDB96 has the logic value 3, each of the stored data bits SDB2~SDB3 has the don’t care logic value X, and the stored data bit SDB1 has the logic value 2.

When the value of the stored data SDT1 has an encoding range 286~288, the value of the stored data SDT1 can be equal to any value in the encoding range 286~288. Correspondingly, each of the stored data bits SDB3~SDB96 has the logic value 3, and each of the stored data bits SDB1~SDB2 has the don’t care logic value X.

In summary, for conditions of the values of the stored data SDT1 smaller than 288, when a quantity of stored data bits having the logic value 3 is larger, the minimum value in the encoding range is larger. For example, when the stored data SDT1 has the encoding range 194~286, the minimum value in the encoding range 194~286 is equal to 194, and the quantity of the stored data bits SDB95~SDB96 having the logic value 3 is equal to 2. When the stored data SDT1 has the encoding range 286~288, the minimum value in the encoding range 286~288 is equal to 286, and the quantity of the stored data bits SDB3~SDB96 having the logic value 3 is equal to 94.

Referring to FIG. 1 and FIG. 2, in various embodiments, the memory device 100 can be implemented by various numbers of memory layers, and the stored data SDT1 can have corresponding quantized values. For example, when the memory device 100 is implemented by MLC three-dimensional cube IMS of 48 memory layers, the stored data SDT1 can have quantized values 0~72. When the memory device 100 is implemented by MLC three-dimensional cube IMS of 96 memory layers, the stored data SDT1 can have quantized values 0~144. When the memory device 100 is implemented by MLC three-dimensional cube IMS of 192 memory layers, the stored data SDT1 can have quantized values 0~288. In summary, when a layer number of the memory device 100 is increased, a range of the quantized values is increased, such that the bit resolution is increased.

In some embodiments, the input data IDT1 also can have the thermometer encoding. Similar to the stored data SDT1, the input data IDT1 also can have encoding ranges. Sizes of the encoding ranges of the input data IDT1 is equal to quantities of the input data bits having the wildcard logic value W. For various encoding ranges, the input data IDT1 can have various values. In some embodiments, the values of the input data IDT1 described above can be referred to as quantized values of the input data IDT1.

In the embodiments of the memory string MS1 being implemented by 192 layers of MLC, the value of the input data IDT1 can be equal to 0 to 288. When the value of the input data IDT1 is smaller than or equal to 96, the value of the input data IDT1 is equal to a quantity of the input data bits in the input data bits IDB1~IDB96 having the logic value 1. When the value of the input data IDT1 is smaller than or equal to 192, the value of the input data IDT1 is proportional to a quantity of the input data bits in the input data bits IDB1~IDB96 having the logic value 2. When the value of the input data IDT1 is smaller than or equal to 288, the value of the input data IDT1 is proportional to a quantity of the input data bits in the input data bits IDB1~IDB96 having the logic value 3.

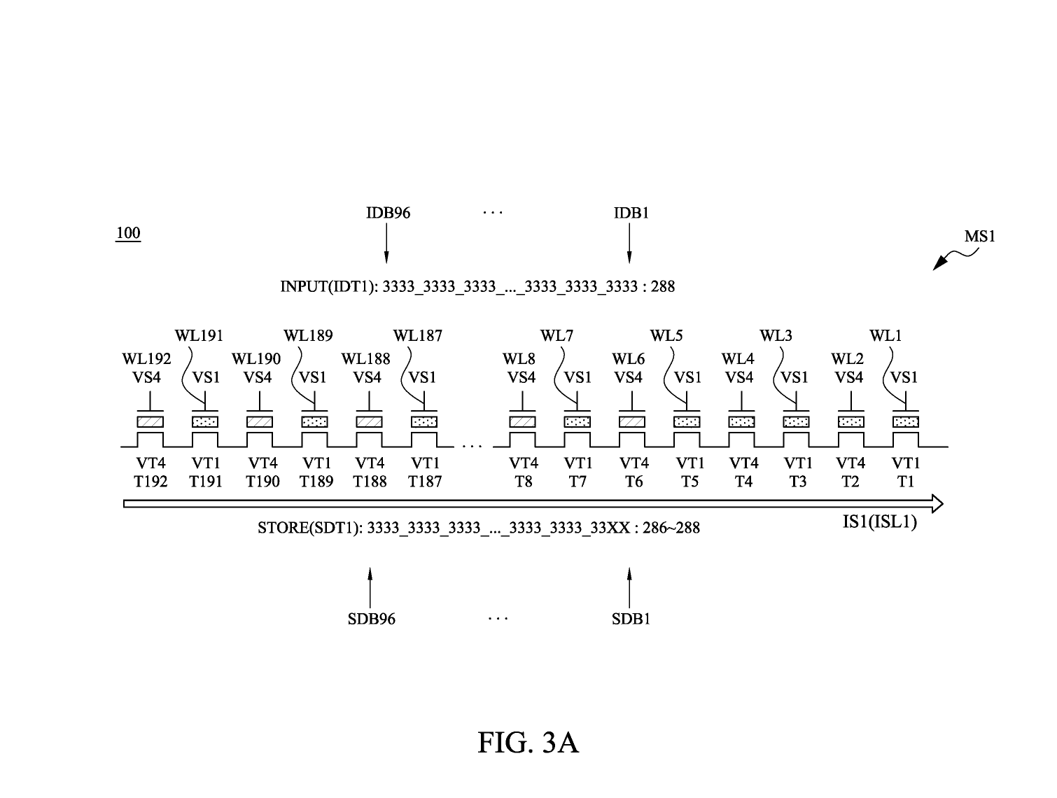

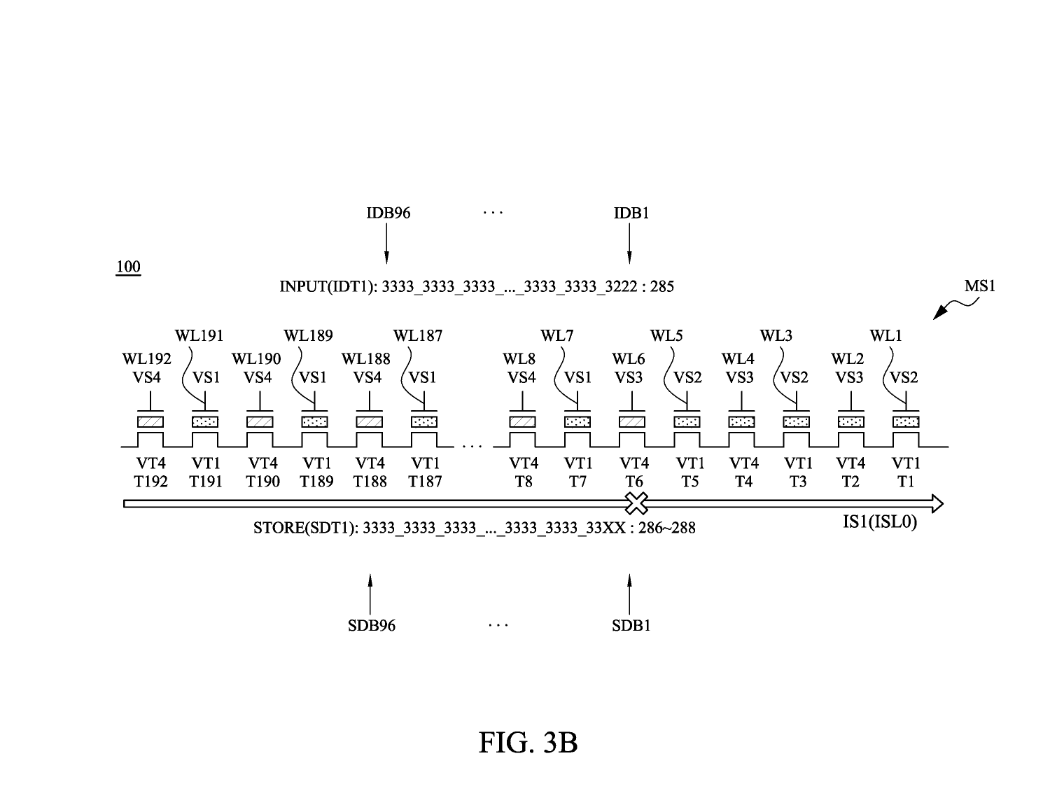

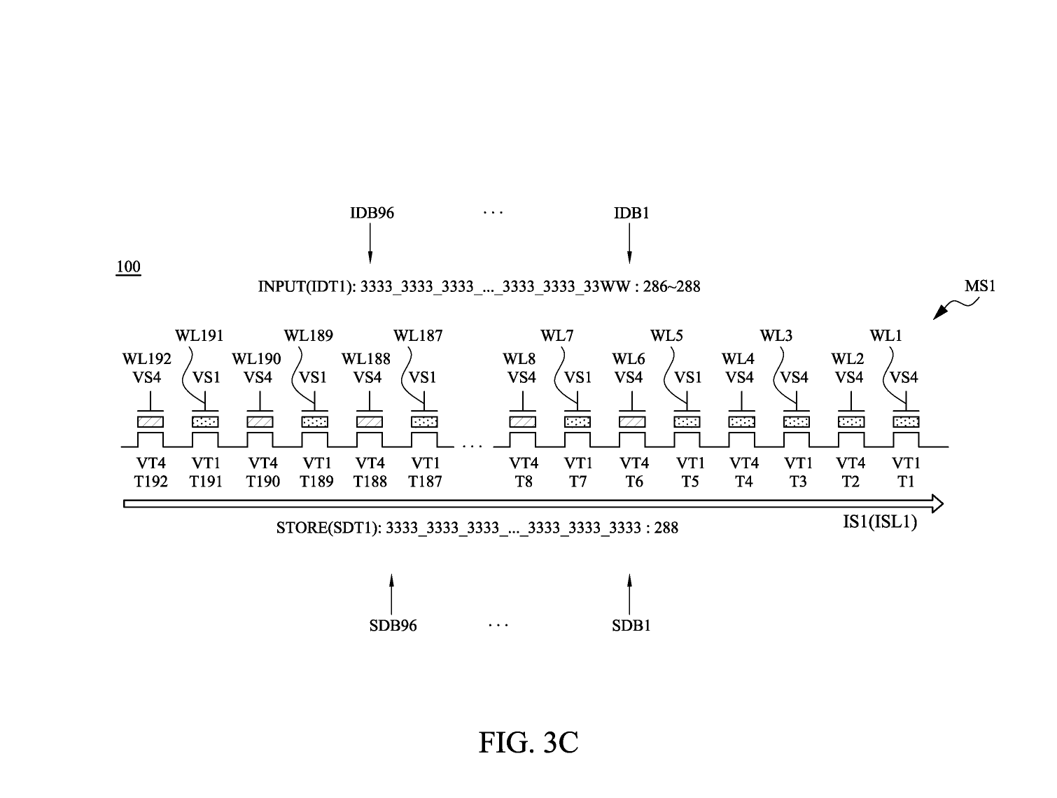

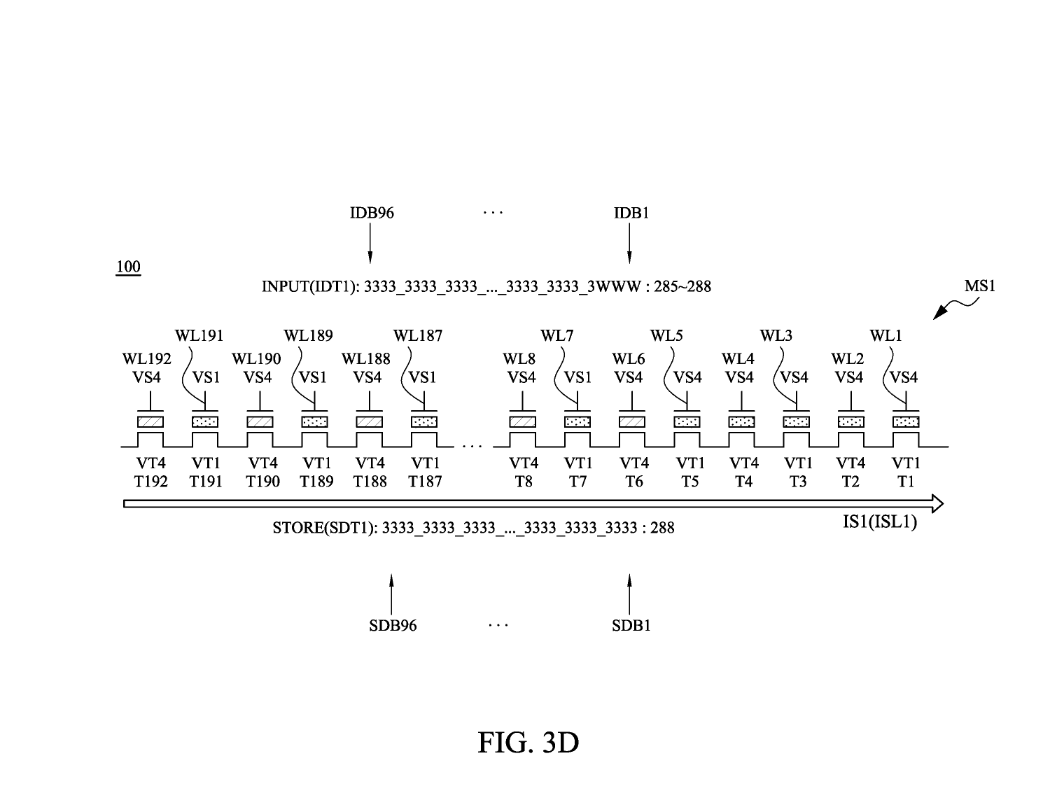

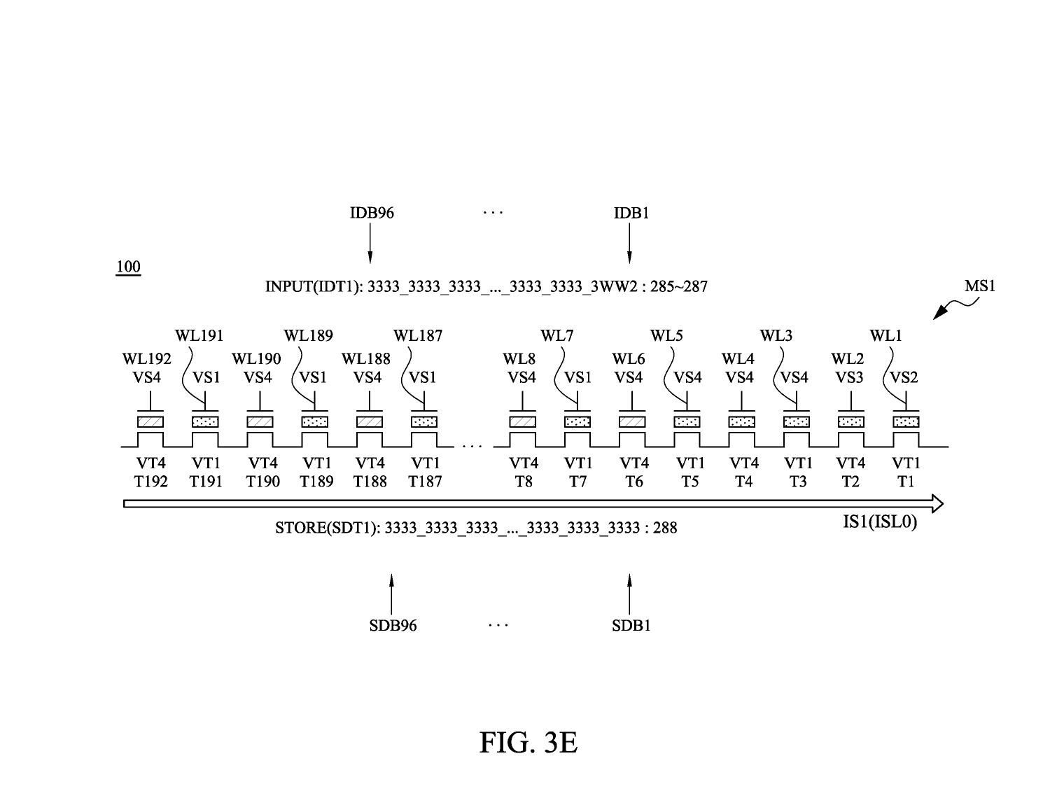

FIG. 3A is a schematic diagram of the memory device 100 performing the search operation, illustrated according to some embodiments of present disclosure. In the embodiment shown in FIG. 3A, the value of the input data IDT1 is equal to 288. Alternatively stated, each of the input data bits IDB1~IDB96 has the logic value 3. Correspondingly, the word line signals WL1~WL192 have the voltage levels VS1, VS4, VS1, VS4, …, VS1, VS4, VS1 and VS4, respectively.

On the other hand, the stored data SDT1 has the encoding range 286~288. Alternatively stated, each of the stored data bits SDB3~SDB96 has the logic value 3, and each of the stored data bits SDB1~SDB2 has the don’t care logic value X. Correspondingly, each of the switch elements T1~T4 has the threshold voltage level VT1, and the switch elements T5~T192 have the threshold voltage levels VT1, VT4, VT1, VT4, …, VT1, VT4, VT1 and VT4, respectively.

In response to the distribution of the voltage levels of the word line signals and the threshold voltage levels of the switch elements described above, each of the switch elements T1~T192 is turned on. Correspondingly, the string current signal IS1 has a current level ISL1, in which the current level ISL1 is larger than the zero current level.

In some embodiments, when the string current signal IS1 has the current level ISL1, the memory device 100 can determine the stored data SDT1 matching the input data IDT1. Alternatively stated, in response to the value 288 of the input data IDT1 being included in the encoding range 286~288 of the stored data SDT1, the memory string MS1 generates the string current signal IS1 having the current level ISL1, such that the memory device 100 can determine the stored data SDT1 matching the input data IDT1.

FIG. 3B is a schematic diagram of the memory device 100 performing the search operation, illustrated according to some embodiments of present disclosure. Referring to FIG. 3B and FIG. 3A, the condition shown in FIG. 3B is an alternative embodiment of the condition shown in FIG. 3A. Therefore, for brevity, some descriptions are not repeated.

Compared with the condition shown in FIG. 3A, in the condition shown in FIG. 3B, the value of the input data IDT1 is equal to 285. Alternatively stated, each of the input data bits IDB4~IDB96 has the logic value 3, and each of the input data bits IDB1~IDB3 has the logic value 2. Correspondingly, the word line signals WL7~WL192 have the voltage levels VS1, VS4, VS1, VS4, …, VS1, VS4, VS1 and VS4, respectively, and the word line signals WL1~WL6 have the voltage levels VS2, VS3, VS2, VS3, VS2 and VS3, respectively.

At this moment, in response to the word line signal WL6 having the voltage level VS3 and the switch element T6 having the threshold voltage level VT4, the switch element T6 is turned off. Correspondingly, the string current signal IS1 has a current level ISL0. In some embodiments, the current level ISL0 is equal to the zero current level.

In some embodiments, when the string current signal IS1 has the current level ISL0, the memory device 100 can determine the stored data SDT1 not matching the input data IDT1. Alternatively stated, in response to the value 285 of the input data IDT1 being out of the encoding range 286~288 of the stored data SDT1, the memory string MS1 generates the string current signal IS1 having the current level ISL0, such that the memory device 100 can determine the stored data SDT1 not matching the input data IDT1.

FIG. 3C is a schematic diagram of the memory device 100 performing the search operation, illustrated according to some embodiments of present disclosure. In the embodiment shown in FIG. 3C, the value of the input data IDT1 has the encoding range 286~288. Alternatively stated, each of the input data bits IDB3~IDB96 has the logic value 3, and each of the input data bits IDB1~IDB2 has the wildcard logic value W. Correspondingly, each of the word line signals WL1~WL4 has the voltage level VS4, and each of the word line signals WL5~WL192 have the voltage levels VS1, VS4, VS1, VS4, …, VS1, VS4, VS1 and VS4, respectively.

On the other hand, the value of the stored data SDT1 is equal to 288. Alternatively stated, each of the stored data bits SDB3~SDB96 has the logic value 3. Correspondingly, the switch elements T1~T192 have the threshold voltage levels VT1, VT4, VT1, VT4, …, VT1, VT4, VT1 and VT4, respectively.

In response to the distribution of the voltage levels of the word line signals and the threshold voltage levels of the switch elements described above, each of the switch elements T1~T192 is turned on. Correspondingly, the string current signal IS1 has a current level ISL1. Alternatively stated, in response to the value 288 of the stored data SDT1 being included in the encoding range 286~288 of the input data IDT1, the memory string MS1 generates the string current signal IS1 having the current level ISL1, such that the memory device 100 can determine the stored data SDT1 matching the input data IDT1.

FIG. 3D is a schematic diagram of the memory device 100 performing the search operation, illustrated according to some embodiments of present disclosure. Referring to FIG. 3D and FIG. 3C, the condition shown in FIG. 3D is an alternative embodiment of the condition shown in FIG. 3C. Therefore, for brevity, some descriptions are not repeated.

Compared with the condition shown in FIG. 3C, in the condition shown in FIG. 3D, the input data IDT1 has an encoding range 285~288. Alternatively stated, each of the input data bits IDB4~IDB96 has the logic value 3, and each of the input data bits IDB1~IDB3 has the wildcard logic value W. Correspondingly, each of the word line signals WL1~WL6 has the voltage level VS4, and each of the word line signals WL7~WL192 have the voltage levels VS1, VS4, VS1, VS4, …, VS1, VS4, VS1 and VS4, respectively.

In response to the distribution of the voltage levels of the word line signals and the threshold voltage levels of the switch elements described above, each of the switch elements T1~T192 is turned on. Correspondingly, the string current signal IS1 has a current level ISL1. Alternatively stated, in response to the value 288 of the stored data SDT1 being included in the encoding range 285~288 of the input data IDT1, the memory string MS1 generates the string current signal IS1 having the current level ISL1, such that the memory device 100 can determine the stored data SDT1 matching the input data IDT1.

FIG. 3E is a schematic diagram of the memory device 100 performing the search operation, illustrated according to some embodiments of present disclosure. Referring to FIG. 3E and FIG. 3C, the condition shown in FIG. 3E is an alternative embodiment of the condition shown in FIG. 3C. Therefore, for brevity, some descriptions are not repeated.

Compared with the condition shown in FIG. 3C, in the condition shown in FIG. 3E, the input data IDT1 has an encoding range 285~287. Alternatively stated, each of the input data bits IDB4~IDB96 has the logic value 3, each of the input data bits IDB2~IDB3 has the wildcard logic value W, and the input data bit IDB1 has the logic value 2. Correspondingly, each of the word line signals WL3~WL6 has the voltage level VS4, the word line signals WL1~WL2 have the voltage levels VS2 and VS3, respectively, and each of the word line signals WL7~WL192 have the voltage levels VS1, VS4, VS1, VS4, …, VS1, VS4, VS1 and VS4, respectively.

At this moment, in response to the word line signal WL2 having the voltage level VS3 and the switch element T2 having the threshold voltage level VT4, the switch element T2 is turned off. Correspondingly, the string current signal IS1 has a current level ISL0. Alternatively stated, in response to the value 288 of the stored data SDT1 being out of the encoding range 285~287 of the input data IDT1, the memory string MS1 generates the string current signal IS1 having the current level ISL0, such that the memory device 100 can determine the stored data SDT1 not matching the input data IDT1.

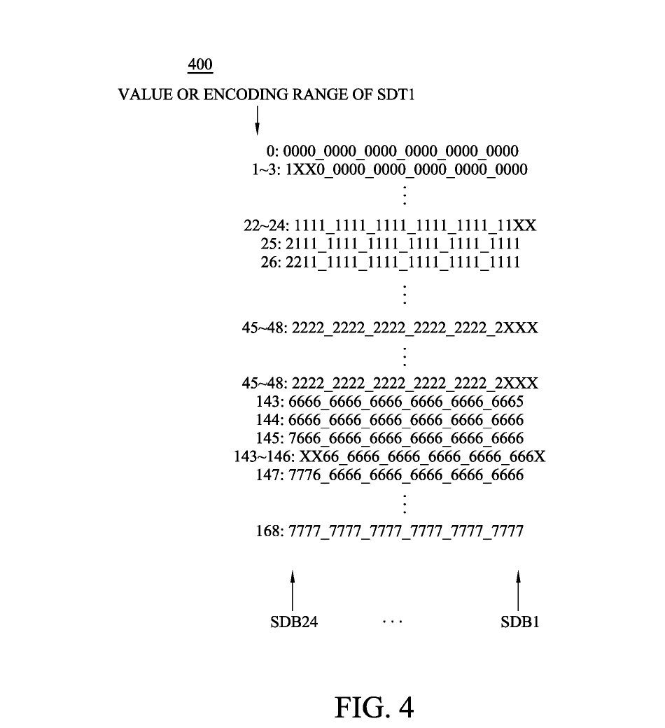

FIG. 4 is a schematic diagram of various values and encoding ranges of the stored data SDT1, illustrated according to some embodiments of present disclosure. In the embodiment shown in FIG. 4, the memory device is implemented by 48 layers of triple level cell (TLC). Correspondingly, the stored data SDT1 includes the stored data bits SDB1~SDB24. Each of the stored data bits SDB1~SDB24 can have anyone of the logic values 0~7. The stored data bits SDB1~SDB24 also can have the don’t care value X, in which the don’t care value X can represent anyone of the logic values 0~7.

As shown in FIG. 4, when the value of the stored data SDT1 is equal to 0, each of the stored data bits SDB1~SDB24 has the logic value 0. When the stored data SDT1 has an encoding range 1~3, each of the stored data bits SDB1~SDB21 has the logic value 0, each of the stored data bits SDB22~SDB23 has the don’t care logic value X, and the stored data bit SDB1 has the logic value 1.

When the stored data SDT1 has an encoding range 22~24, each of the stored data bits SDB1~SDB2 has the don’t care logic value X, and each of the stored data bits SDB3~SDB24 has the logic value 1. When the value of the stored data SDT1 is equal to 25, each of the stored data bits SDB1~SDB23 has the logic value 1, and the stored data bit SDB24 has the logic value 2.

When the value of the stored data SDT1 is equal to 26, each of the stored data bits SDB1~SDB22 has the logic value 1, and each of the stored data bits SDB23~SDB24 has the logic value 2. When the stored data SDT1 has an encoding range 45~48, each of the stored data bits SDB1~SDB3 has the don’t care logic value X, and each of the stored data bits SDB4~SDB24 has the logic value 1.

When the value of the stored data SDT1 is equal to 142, each of the stored data bits SDB1~SDB2 has the logic value 5, and each of the stored data bits SDB3~SDB24 has the logic value 6. When the value of the stored data SDT1 is equal to 143, the stored data bit SDB1 has the logic value 5, and each of the stored data bits SDB2~SDB24 has the logic value 6.

When the value of the stored data SDT1 is equal to 144, each of the stored data bits SDB1~SDB24 has the logic value 6. When the value of the stored data SDT1 is equal to 145, the stored data bit SDB24 has the logic value 7, and each of the stored data bits SDB1~SDB23 has the logic value 6.

When the stored data SDT1 has an encoding range 143~146, each of the stored data bits SDB1 and SDB23~SDB24 has the don’t care logic value X, and each of the stored data bits SDB2~SDB22 has the logic value 6. When the value of the stored data SDT1 is equal to 147, each of the stored data bits SDB22~SDB24 has the logic value 7, and each of the stored data bits SDB1~SDB21 has the logic value 6. When the value of the stored data SDT1 is equal to 168, each of the stored data bits SDB1~SDB24 has the logic value 7.

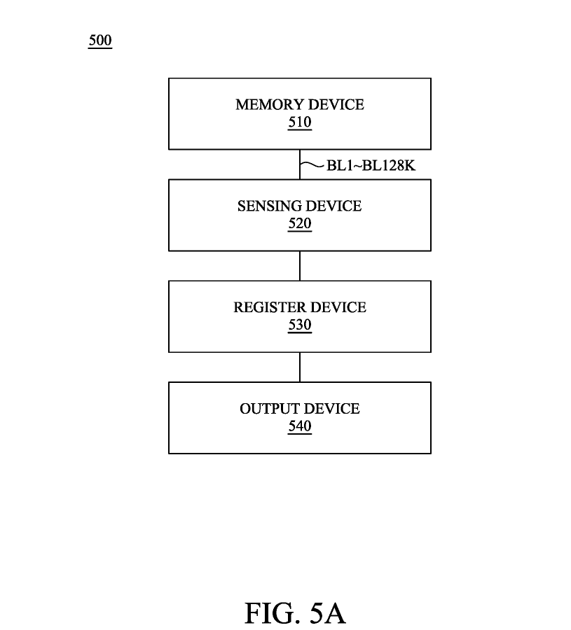

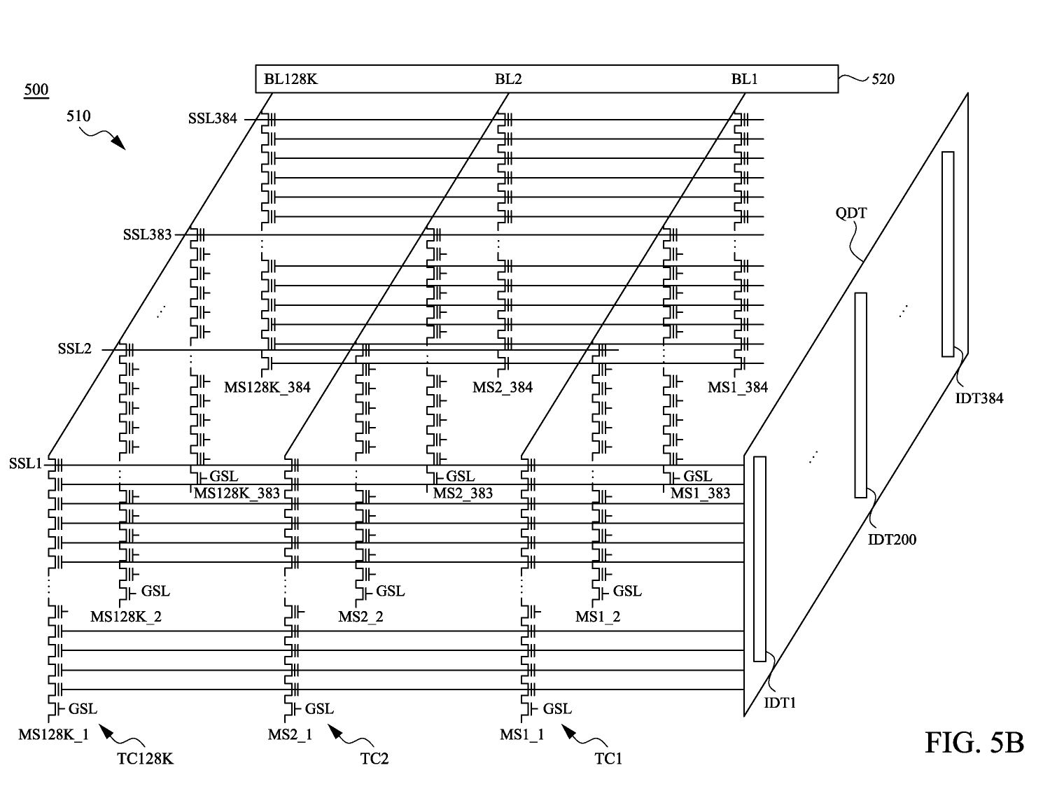

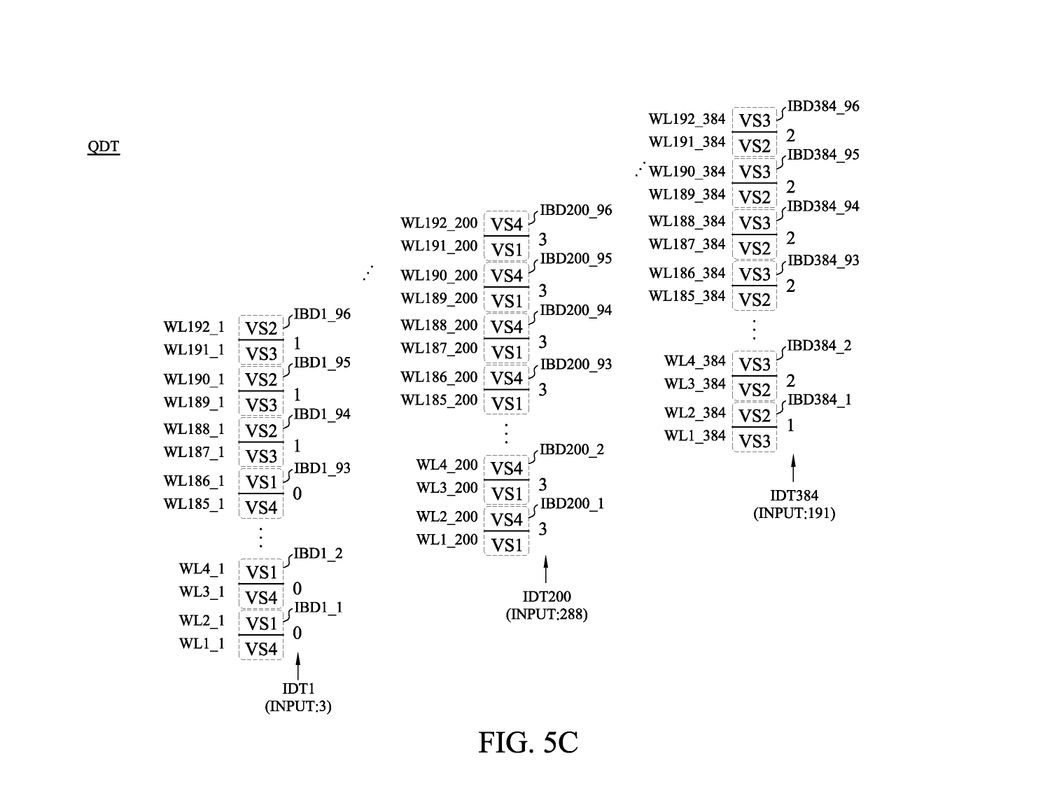

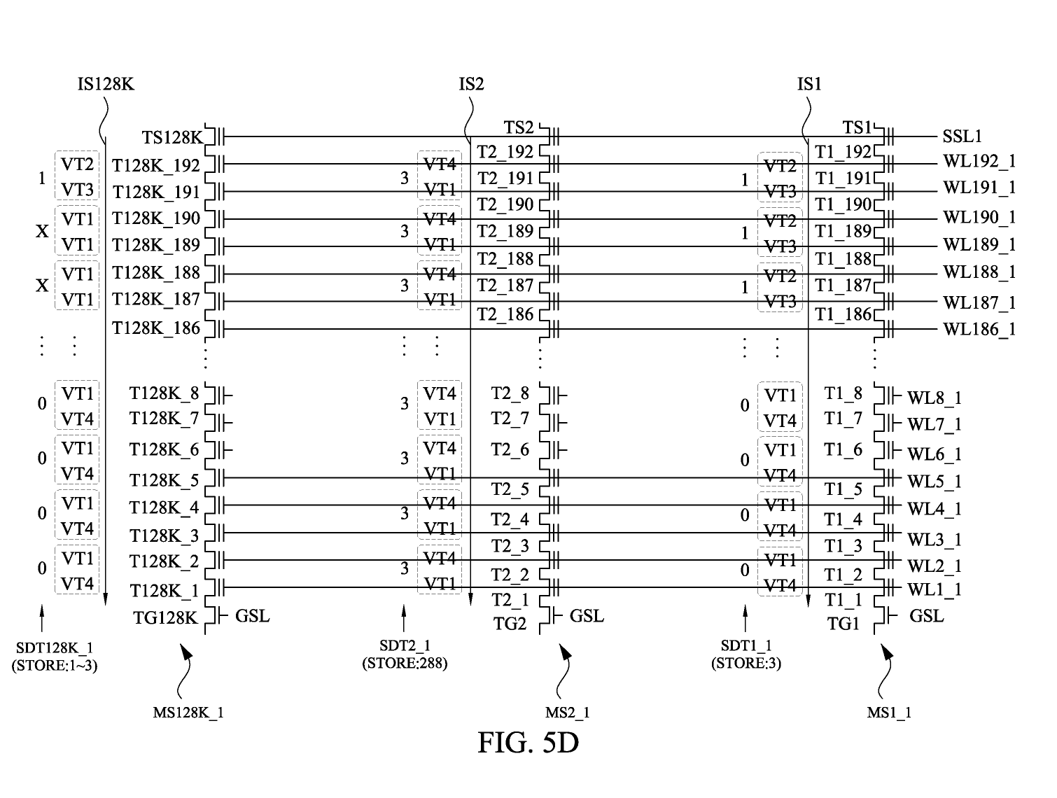

FIG. 5A is a schematic diagram of a memory system 500 illustrated according to some embodiments of present disclosure. As shown in FIG. 5A, the memory system 500 includes a memory device 510, a sensing device 520, a register device 530 and an output device 540.

In some embodiments, the memory device 510 is configured to generate bit line signals BL1-BL128K. The sensing device 520 can include a page buffer and a sensing amplifier, and configured to sense corresponding searching results of the bit line signals BL1-BL128K. The register device 530 can includes cache registers and priority encoders. The output device 540 is configured to output the matching results of the memory device 510.

In some embodiments, the process performed by the register device 530 to the bit line signals includes logic processes of AND logic, OR logic or counting, and also may include combining processes of the three logic processes described above. Referring to FIG. 1 to FIG. 5A, the register device 530 can receive sense results from the memory device 100 and/or 510, and controls sequencing (whether serial or parallel) and combines sense results to produce overall search results as the matching results outputted from the output device 540.

In some embodiments, the register device 530 is further configured to perform priority encoding to the corresponding searching results of the bit line signals BL1-BL128K. For example, the register device 530 collectively processes the corresponding searching results of the bit line signals BL1-BL128K, and preferentially select an address of a bit line signal corresponding to the best searching result (that is, the value of the input data and the value of the stored data are closest to each other).

FIG. 5B is schematic diagram of further details of the memory system 500 shown in FIG. 5A, illustrated according to some embodiments of present disclosure. As shown in FIG. 5B, the memory device 510 includes multiple text chunks TC1~TC128K. The text chunks TC1~TC128K are configure to generate the bit line signals BL1-BL128K, respectively, and transmit the bit line signals BL1-BL128K to the sensing device 520. However, the present disclosure is not limited to this. In various embodiments, the memory device 510 can include various quantities of text chunks. Alternatively stated, 128K can be substituted by other positive integers.

In some embodiments, each of the text chunks TC1~TC128K includes multiple memory strings. For example, the text chunk TC1 includes memory strings MS1_1~MS1_384. The text chunk TC2 includes memory strings MS2_1~MS2_384, and so on. The text chunk TC128K includes memory strings MS128K_1~MS128K_384. However, the present disclosure is not limited to this. In various embodiments, the text chunk can include various quantities of memory strings. Alternatively stated, 384 can be substituted by other positive integers.

Referring to FIG. 1 and FIG. 5B, each of configurations of the memory strings MS1_1~MS128K_384 is similar to the configuration of the memory string MS1. For example, the encoding method of each of the memory strings MS1_1~MS128K_384 can be similar to the encoding method shown in FIG. 3A to FIG. 3E. Therefore, for brevity, some descriptions are not repeated.

As shown in FIG. 5B, each of the memory strings MS1_1~MS128K_384 is configured to receive a ground select line signal GSL. Each of the memory strings MS1_1~MS128K_1 is configured to receive a string select line signal SSL1. Each of the memory strings MS1_2~MS128K_2 is configured to receive a string select line signal SSL2, and so on. Each of the memory strings MS1_383~MS128K_383 is configured to receive a string select line signal SSL383. Each of the memory strings MS1_384~MS128K_384 is configured to receive a string select line signal SSL384.

In some embodiments, the memory strings MS1_1~MS1_384 are configured to store stored data SDT1_1~SDT1_384, respectively. The memory strings MS2_1~MS2_384 are configured to store stored data SDT2_1~SDT2_384, respectively, and so on. The memory strings MS128K_1~MS128K_384 are configured to store stored data SDT128K_1~SDT128K_384, respectively. Further details regarding the stored data and the memory strings are described below in the embodiments associated with FIG. 5D.

On the other hand, each of the text chunks TC1~TC128K is configured to receive query data QDT, to compare the query data QDT with corresponding stored data. Specifically, the query data QDT includes input data IDT1~IST384. Further details regarding the query data QDT are described below in the embodiments associated with FIG. 5C.

In some embodiments, the memory strings MS1_1~MS128K_1 are configured to compare the input data IDT1 with the stored data SDT1_1~SDT128K_1, respectively, to generate corresponding string current signals. The memory strings MS1_2~MS128K_2 are configured to compare the input data IDT2 with the stored data SDT1_2~SDT128K_2, respectively, to generate corresponding string current signals, and so on. The memory strings MS1_383~MS128K_383 are configured to compare the input data IDT383 with the stored data SDT1_383~SDT128K_383, respectively, to generate corresponding string current signals. The memory strings MS1_384~MS128K_384 are configured to compare the input data IDT384 with the stored data SDT1_384~SDT128K_384, respectively, to generate corresponding string current signals.

Then, the memory strings MS1_1~MS1_384 are configured to sum corresponding string current signals to generate the bit line signal BL1. The memory strings MS2_1~MS2_384 are configured to sum corresponding string current signals to generate the bit line signal BL2, and so on. The memory strings MS128K_1~MS128K_384 are configured to sum corresponding string current signals to generate the bit line signal BL128K.

FIG. 5C is schematic diagram of further details of the query data QDT, illustrated according to some embodiments of present disclosure. As shown in FIG. 5C, the query data QDT can be carried by word line signals.

Specifically, word line signals WL1_1~WL192_1 are configured to carry the input data IDT1. Word line signals WL1_2~WL192_2 are configured to carry the input data IDT2, and so on. Word line signals WL1_200~WL192_200 are configured to carry the input data IDT200. Word line signals WL1_384~WL192_384 are configured to carry the input data IDT384.

Referring to FIG. 3A to FIG. 3E and FIG. 5C, a relationship between the word line signals WL1_1~WL192_1 and the input data IDT1, a relationship between the word line signals WL1_200~WL192_200 and the input data IDT200 and a relationship between the word line signals WL1_384~WL192_384 and the input data IDT384 are similar to the relationship between the word line signals WL1~WL192 and the input data IDT1. Therefore, for brevity, some descriptions are not repeated.

In the embodiment shown in FIG. 5C, the input data IDT1 includes input data bits IDB1_1~IDB1_96. The word line signals WL1_1 and WL2_1 are configured to carry the input data bit IDB1_1. The word line signals WL3_1 and WL4_1 are configured to carry the input data bit IDB1_2, and so on. The word line signals WL185_1 and WL186_1 are configured to carry the input data bit IDB1_93. The word line signals WL187_1 and WL188_1 are configured to carry the input data bit IDB1_94. The word line signals WL189_1 and WL190_1 are configured to carry the input data bit IDB1_95. The word line signals WL191_1 and WL192_1 are configured to carry the input data bit IDB1_96.

Similarly, the input data IDT200 includes input data bits IDB200_1~IDB200_96. The word line signals WL1_200 and WL2_200 are configured to carry the input data bit IDB200_1. The word line signals WL3_200 and WL4_200 are configured to carry the input data bit IDB200_2, and so on. The word line signals WL185_200 and WL186_200 are configured to carry the input data bit IDB200_93. The word line signals WL187_200 and WL188_200 are configured to carry the input data bit IDB200_94. The word line signals WL189_200 and WL190_200 are configured to carry the input data bit IDB200_95. The word line signals WL191_200 and WL192_200 are configured to carry the input data bit IDB200_96.

Similarly, the input data IDT384 includes input data bits IDB384_1~IDB384_96. The word line signals WL1_384 and WL2_384 are configured to carry the input data bit IDB384_1. The word line signals WL3_384 and WL4_384 are configured to carry the input data bit IDB384_2, and so on. The word line signals WL185_384 and WL186_384 are configured to carry the input data bit IDB384_93. The word line signals WL187_384 and WL188_384 are configured to carry the input data bit IDB384_94. The word line signals WL189_384 and WL190_384 are configured to carry the input data bit IDB384_95. The word line signals WL191_384 and WL192_384 are configured to carry the input data bit IDB384_96.

In the embodiment shown in FIG. 5C, the value of the input data IDT1 is equal to 3. Alternatively stated, each of the input data bits IDB1_1~IDB1_3 has the logic value 0, and each of the input data bits IDB1_4~IDB1_96 has the logic value 1. Correspondingly, the word line signals WL1_1~WL188_1 have voltage levels VS4, VS1, VS4, VS1, …, VS4, VS1, VS4 and VS1, respectively, and the word line signals WL189_1~WL192_1 have voltage levels VS3, VS2, VS3 and VS2, respectively.

Furthermore, the value of the input data IDT200 is equal to 288. Alternatively stated, each of the input data bits IDB200_1~IDB200_96 has the logic value 3. Correspondingly, the word line signals WL1_200~WL192_200 have voltage levels VS4, VS1, VS4, VS1, …, VS4, VS1, VS4 and VS1, respectively.

Furthermore, the value of the input data IDT384 is equal to 191. Alternatively stated, the input data bit IDB384_1 has the logic value 1, and each of the input data bits IDB384_2~IDB192_384 has the logic value 2. Correspondingly, the word line signals WL3_384~WL192_384 have voltage levels VS2, VS3, VS2, VS3, …, VS2, VS3, VS2 and VS3, respectively, and the word line signals WL1_384 and WL2_384 have voltage levels VS3 and VS2, respectively.

FIG. 5D is schematic diagram of further details of the memory strings MS1_1~MS128K_1, illustrated according to some embodiments of present disclosure. As shown in FIG. 5D, the memory string MS1_1 includes switch elements TG1, T1_1~T1_192 and TS1 coupled in series with each other and arranged in order. The memory string MS2_1 includes switch elements TG2, T2_1~T2_192 and TS2 coupled in series with each other and arranged in order, and so on. The memory string MS128K_1 includes switch elements TG128K, T128K_1~T128K_192 and TS128K coupled in series with each other and arranged in order.

In some embodiments, each of control terminals of the switch elements TG1~TG128K is configured to receive the ground select line signal GSL. Each of control terminals of the switch elements T1_1~T128K_1 is configured to receive the word line signal WL1_1. Each of control terminals of the switch elements T1_2~T128K_2 is configured to receive the word line signal WL2_1, and so on. Each of control terminals of the switch elements T1_191~T128K_191 is configured to receive the word line signal WL191_1. Each of control terminals of the switch elements T1_192~T128K_192 is configured to receive the word line signal WL192_1.

Referring to FIG. 1 and FIG. 5D, a configuration of the switch elements T1_1~T1_192, a configuration of the switch elements T2_1~T2_192 and a configuration of the switch elements T128K_1~T128K_192 are similar to the configuration of the switch elements T1~T192. A configuration of the word line signals WL1_1~WL192_1 is similar to the configuration of the word line signals WL1~WL192. Therefore, for brevity, some descriptions are not repeated.

In some embodiments, the stored data SDT1_1 includes stored data bits SDB1_1_1~SDB1_1_96. The stored data SDT2_1 includes stored data bits SDB2_1_1~SDB2_1_96, and so on. The stored data SDT128K_1 includes stored data bits SDB128K_1_1~SDB128K_1_96.

Correspondingly, the switch elements T1_1 and T1_2 are configured to store the stored data bit SDB1_1_1. The switch elements T1_3 and T1_4 are configured to store the stored data bit SDB1_1_2, and so on. The switch elements T1_189 and T1_190 are configured to store the stored data bit SDB1_1_95. The switch elements T1_191 and T1_192 are configured to store the stored data bit SDB1_1_96.

Similarly, the switch elements T2_1 and T2_2 are configured to store the stored data bit SDB2_1_1. The switch elements T2_3 and T2_4 are configured to store the stored data bit SDB2_1_2, and so on. The switch elements T2_189 and T2_190 are configured to store the stored data bit SDB2_1_95. The switch elements T2_191 and T2_192 are configured to store the stored data bit SDB2_1_96.

Similarly, the switch elements T128K_1 and T128K_2 are configured to store the stored data bit SDB128K_1_1. The switch elements T128K_3 and T128K_4 are configured to store the stored data bit SDB128K_1_2, and so on. The switch elements T128K_189 and T128K_190 are configured to store the stored data bit SDB128K_1_95. The switch elements T128K_191 and T128K_192 are configured to store the stored data bit SDB128K_1_96.

In the embodiment shown in FIG. 5D, the value of the stored data SDT1_1 stored by the memory string MS1_1 is equal to 3. Alternatively stated, each of the stored data bits SDB1_1_1~SDB1_1_93 has the logic value 0, and each of the stored data bits SDB1_1_94~SDB1_1_96 has the logic value 1. Correspondingly, the switch elements T1_1~T1_186 has the threshold voltage levels VT4, VT1, VT4, VT1, …, VT4, VT1, VT4 and VT1, respectively, and the switch elements T1_197~T1_192 has the threshold voltage levels VT3, VT2, VT3, VT2, VT3 and VT2, respectively.

Furthermore, the value of the stored data SDT2_1 stored by the memory string MS2_1 is equal to 288. Alternatively stated, each of the stored data bits SDB2_1_1~SDB2_1_96 has the logic value 3. Correspondingly, the switch elements T2_1~T2_192 has the threshold voltage levels VT1, VT4, VT1, VT4, …, VT1, VT4, VT1 and VT4, respectively.

Furthermore, the stored data SDT128K_1 stored by the memory string MS128K_1 has the encoding range 1~3. Alternatively stated, each of the stored data bits SDB128K_1_1~SDB128K_1_93 has the logic value 0, each of the stored data bits SDB128K_1_94~SDB128K_1_95 has the don’t care logic value X, and the stored data bits SDB128K_1_96 has the logic value 1. Correspondingly, the switch elements T128K_1~T128K_186 has the threshold voltage levels VT4, VT1, VT4, VT1, …, VT4, VT1, VT4 and VT1, respectively, each of the switch elements T128K_187~T128K_190 has the threshold voltage level VT1, the switch elements T128K_191~T128K_192 has the threshold voltage levels VT3 and VT2, respectively.

Referring to FIG. 5C and FIG. 5D, the memory string MS1_1 can compare the stored data SDT1_1 and the input data IDT1 to generate a string current signal IS1. In response to the value of the stored data SDT1_1 is equal to 3 and the value of the input data IDT1 is also equal to 3, each of the switch elements T1_1~T1_192 is turned on, such that the string current signal IS1 has the current level ISL1.

Similarly, the memory string MS2_1 can compare the stored data SDT2_1 and the input data IDT1 to generate a string current signal IS2. In response to the value of the stored data SDT2_1 is equal to 288 and the value of the input data IDT1 is equal to 3, the switch elements having the threshold voltage level VT4 and having the voltage level VS1 at the control terminals are turned off. Alternatively stated, each of the switch elements T2_2, T2_4, …, T2_190 and T2_192 is turned off, such that the string current signal IS2 has the current level ISL0.

Similarly, the memory string MS128K_1 can compare the stored data SDT1128K_1 and the input data IDT1 to generate a string current signal IS128K. In response to the stored data SDT128K_1 has the encoding range 1~3 and the value of the input data IDT1 is also equal to 3 (that is, the value of the input data IDT1 is within the encoding range of the stored data SDT128K_1), each of the switch elements T1_1~T1_192 is turned on, such that the string current signal IS1 has the current level ISL1.

In some embodiments, the memory cells in present disclosure are referred to as in-memory searching (IMS) cells. In various embodiments, the IMS cells can be implemented by floating gate memory, split-gate memory, silicon-oxide-nitride-oxide-silicon (SONOS) memory, floating dot memory, dynamic random-access memory (DRAM) and/or ferroelectric field-effect transistor (FeFET).

In various embodiments, the memory devices described in the present disclosure can be implemented by various structures, such as 2D flash structure or 3D flash structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising a memory string configured to store first stored data, and configured to compare the first stored data and first input data to generate a first current signal, the memory string comprising a plurality of switch elements coupled in series with each other, the plurality of switch elements comprising:
a first switch element configured to have a first threshold voltage when the first stored data has a first value, and have a second threshold voltage when the first stored data has a first encoding range; and
a second switch element configured to have the second threshold voltage when the first stored data has the first value, and have the second threshold voltage when the first stored data has the first encoding range,
wherein the first encoding range at least comprises the first value and a second value different from the first value.

2. The memory device of claim 1, wherein the memory string is further configured to receive a plurality of word line signals,
the plurality of word line signals are configured to carry the first input data,
when the first input data has the first value and the first stored data have the first encoding range, the first current signal has a first current level.

3. The memory device of claim 2, wherein when the first input data has a third value and the first stored data have the first encoding range, the first current signal has a second current level.

4. The memory device of claim 3, wherein the third value is out of the first encoding range, and
the second current level is smaller than the first current level.

5. The memory device of claim 2, wherein
a control terminal of the first switch element is configured to receive a first word line signal in the plurality of word line signals,
a control terminal of the second switch element is configured to receive a second word line signal in the plurality of word line signals,
when the first stored data has the first value, the first word line signal and the second word line signal have a first voltage level and a second voltage level, respectively, and
when the first stored data has the first encoding range, each of the first word line signal and the second word line signal has the first voltage level.

6. The memory device of claim 5, wherein when the first stored data has the first encoding range, a third word line signal in the plurality of word line signals has the second voltage level,
when the first stored data has a second encoding range, the third word line signal has the first voltage level, and
the second encoding range is larger than the first encoding range.

7. The memory device of claim 6, wherein the first voltage level is larger than the second voltage level.

8. The memory device of claim 6, wherein when the first stored data has a third encoding range, the first word line signal and the second word line signal have a third voltage level and a fourth voltage level, respectively, and
the first voltage level, the second voltage level, the third voltage level and the fourth voltage level are different from each other.

9. The memory device of claim 8, wherein each of the third voltage level and the fourth voltage level is between the first voltage level and the second voltage level.

10. The memory device of claim 8, wherein when the first stored data has the third encoding range and the first stored data has the first value, the first current signal has a second current level.

11. The memory device of claim 10, wherein the first value is out of the third encoding range, and the second current level is smaller than the first current level.

12. The memory device of claim 10, wherein when the first stored data has the third encoding range and the first stored data has the first value, the first switch element is turned off.

13. A memory device, comprising a memory string configured to store first stored data, and configured to compare the first stored data and first input data to generate a first current signal, the memory string comprising a plurality of switch elements coupled in series with each other, the plurality of switch elements comprising:
a first switch element configured to receive a first word line signal, have a first threshold voltage when the first stored data has a first value, and have a second threshold voltage when the first stored data has a first encoding range; and
a second switch element configured to receive a second word line signal, have the second threshold voltage when the first stored data has the first value, and have the second threshold voltage when the first stored data has the first encoding range,
wherein the first encoding range at least comprises the first value and a second value different from the first value.

14. The memory device of claim 13, wherein
when the first input data has the first value, the first word line signal and the second word line signal have a first voltage level and a second voltage level, respectively, and
when the first stored data has the first encoding range, each of the first word line signal and the second word line signal has the first voltage level.

15. The memory device of claim 14, wherein when the first input data has a third value, the first word line signal and the second word line signal have a third voltage level and a fourth voltage level, respectively, and
the first voltage level, the second voltage level, the third voltage level and the fourth voltage level are different from each other.

16. The memory device of claim 15, wherein when the first input data has the third value and the first stored data has the first encoding range, a third switch element in the plurality of switch element is turned off, and
the third value is out of the first encoding range.

17. The memory device of claim 14, wherein when the first stored data has the first encoding range, each of the first word line signal and the second word line signal has the first voltage level.

18. A memory system, comprising a plurality of text chunk configured to generate a plurality of bit line signals, respectively, and comprising a plurality of memory strings, the plurality of memory strings comprising:
a first memory string configured to store first stored data, configured to receive a plurality of word line signals carrying first input data, and configured to compare the first stored data and the first input data to generate a first current signal,
wherein in response to the first input data has a first encoding range and the first stored data has a first value, the first current signal has a first current level, and
the first encoding range includes the first value.

19. The memory system of claim 18, wherein the first encoding range further includes a second value different from the first value.

20. The memory system of claim 18, wherein in response to the first input data has the first encoding range, each of at least two switch elements in the first memory string has a first threshold voltage level, and
the at least two switch elements are arranged in order.
